(19) United States
(12) Patent Application Publication
(10) Pub. No.: US 2014/0103428 A1
(43) Pub. Date: Apr. 17, 2014

(54) TRENCH SUPERJUNCTION MOSFET WITH THIN EPI PROCESS

(71) Applicant: Fairchild Semiconductor Corporation, South Portland, ME (US)

(72) Inventor: Suku Kim, South Jordan, UT (US)

(73) Assignee: Fairchild Semiconductor Corporation, South Portland, ME (US)

(21) Appl. No.: 14/141,340

(22) Filed: Dec. 26, 2013

Related U.S. Application Data
(63) Continuation of application No. 12/841,774, filed on Jul. 22, 2010.

(51) Int. Cl. H01L 29/78

(52) U.S. Cl. CPC H01L 29/7813
USPC 257/330

(57) ABSTRACT

Methods for fabricating MOSFET devices with superjunction having high breakdown voltages (>600 volts) with competitively low specific resistance include growing an epitaxial layer of a second conductivity type on a substrate of a first conductivity type, forming a trench in the epitaxial layer, and growing a second epitaxial layer along the sidewalls and bottom of the trench. The second epitaxial layer is doped with a dopant of first conductivity type. MOSFET devices with superjunction having high breakdown voltages include a first epitaxial layer of a second conductivity type disposed over a substrate of a first conductivity type and a trench formed in the epitaxial layer. The trench includes a second epitaxial layer grown along the sidewalls and bottom of the trench.

### CROSS-REFERENCE TO RELATED APPLICATION

This application is a Continuation of, and claims priority to, U.S. patent application Ser. No. 12/841,774, filed Jul. 22, 2010, entitled “TRENCH SUPERJUNCTION MOSFET WITH THIN EPI PROCESS”, the disclosure of which is incorporated by reference herein in its entirety.

### BACKGROUND

The present invention relates to semiconductor power device technology and more particularly to improved trench superjunction MOSFET devices and fabrication processes for forming such devices.

Semiconductor packages are well known in the art. These packages can sometimes include one or more semiconductor devices, such as an integrated circuit (IC) device, die or chip. The IC devices can include electronic circuits that have been manufactured on a substrate made of semiconductor material. The circuits are made using many known semiconductor processing techniques such as deposition, etching photolithography, annealing, doping and diffusion. Silicon wafers are typically used as the substrate on which these IC devices are formed.

An example of a semiconductor device is a metal oxide silicon field effect transistor (MOSFET) device, which is used in numerous electronic apparatuses including power supplies, automotive electronics, computers and disc drives. MOSFET devices can be used in a variety of application such as switches that connect power supplies to particular electronic devices having a load. MOSFET devices can be formed in a trench that has been etched into a substrate or onto an epitaxial layer that has been deposited onto a substrate.

MOSFET devices operate by applying an appropriate voltage to a gate electrode of a MOSFET device which turns the device ON and forms a channel connecting a source and a drain of the MOSFET allowing a current to flow. Once the MOSFET device is turned on, the relation between the current and the voltage is nearly linear which means that the device behaves like a resistance. When the MOSFET device is turned OFF (i.e. in an off state), the voltage blocking capability is limited by the breakdown voltage. In high power applications, it is desirable to have a high breakdown voltage, for example, 600V or higher, while still maintaining low specific resistance Rsp.

Techniques that are employed to increase the breakdown voltage of a MOSFET device with superjunction typically reduces on state specific resistance compared to the nonsupetjunction devices. Therefore, what is needed is a cost effective way of improving the breakdown voltage of a MOSFET device with superjunction, which maximizes reduction of the on specific resistance.

### BRIEF SUMMARY

Embodiments of the present invention provide techniques for fabricating MOSFET device with superjunction having high breakdown voltages (2:600 volts) with competitively low specific resistance. However, this invention can be also used for any other breakdown voltage ranges (e.g. lower than 600V). The techniques for fabricating these MOSFET devices with superjunctions will reduce the fabrication costs and can reduce the on specific resistance further as compared with conventional techniques. These techniques include growing a thin epitaxial layer on the sidewalls and bottom of a trench using epitaxial growth techniques. These techniques are better for manufacturing than are sidewall doping techniques and are more suitable for high voltage MOSFET devices than angled implants.

In one embodiment, a method of fabricating a semiconductor device includes growing an epitaxial layer of a second conductivity type on a substrate of a first conductivity type, forming a trench in the epitaxial layer, growing a second epitaxial layer along the sidewalls and bottom of the trench, the second epitaxial layer is doped with a dopant of first conductivity type, depositing a dielectric material into the trench having the second epitaxial layer lining its sidewalls and bottoms, the dielectric can fill the trench fully and be later etched back to a certain depth, growing or depositing a gate oxide over the dielectric materials and along the sidewalls of the trench above the dielectric material, and forming a polysilicon gate above the gate oxide layer.

In another embodiment, the method can further include diffusing the dopant in the second epitaxial layer into a mesa area to achieve charge balance in a p/n superjunction of the semiconductor device.

In yet another embodiment, the method can further include selecting a concentration of the dopant to achieve charge balance in a p/n superjunction of the semiconductor device without diffusing the dopants.

In yet another embodiment, the method can further include growing a thermal oxide layer in the trench over the second epitaxial layer, wherein the thermal oxide lines the second epitaxial layer in the trench.

In yet another embodiment, the method can further include growing a lightly doped first conductivity type epitaxial layer between the substrate and the second conductivity type epitaxial layer before the dielectric deposition.

In yet another embodiment of the method, the second conductivity type epitaxial layer can further include multiple layers with different doping concentrations.

In yet another embodiment of the method, the trench has an angle that varies according to a current path and a trench fill.

In another embodiment, a second method of fabricating a semiconductor device includes growing an epitaxial layer of a first conductivity type on a substrate of first conductivity type, forming a trench in the epitaxial layer, growing a second epitaxial layer along the sidewalls and bottom of the trench, the second epitaxial layer is doped with a dopant of second conductivity type, depositing a dielectric material into the trench having the second epitaxial layer lining its sidewalls and bottoms, the dielectric can fill the trench fully and be later etched back to a certain depth, growing or depositing a gate oxide over the dielectric materials and along the sidewalls of the trench above the dielectric material, and forming a polysilicon gate above the gate oxide layer.

In yet another embodiment, the second method can further include diffusing the dopant in the second epitaxial layer into a mesa area to achieve charge balance in a p/n supetjunction of the semiconductor device.

In yet another embodiment, the second method can further include selecting a concentration of the dopant to achieve charge balance in a p/n supetjunction of the semiconductor device without diffusing the dopants.

In yet another embodiment, the second method can further include growing a thermal oxide layer in the trench over the second epitaxial layer, wherein the thermal oxide lines the second epitaxial layer in the trench.

In yet another embodiment, the second method can further include growing a lightly doped first conductivity type epitaxial layer between the substrate and the first conductivity type epitaxial layer before the dielectric deposition.

In yet another embodiment of the second method, the second conductivity type epitaxial layer further includes multiple layers with different doping concentrations.

In yet another embodiment of the second method, the trench has an angle that varies according to a current path and a trench fill.

In another embodiment, a semiconductor device includes a first epitaxial layer of a second conductivity type disposed over a substrate of a first conductivity type and a trench formed in the epitaxial layer. The trench includes a second epitaxial layer grown along the sidewalls and bottom of the trench and a dielectric material disposed in the trench in between the second epitaxial layer and filling a portion of the trench, a gate oxide layer disposed over the dielectric material and over the second epitaxial layer along the sidewalls of the trench which is not covered by the dielectric, and a gate disposed over the gate oxide layer. The second epitaxial layer is doped with a dopant of first conductivity type.

In yet another embodiment, the semiconductor device can further include a mesa disposed between a plurality of trenches, wherein the mesa is diffused with dopants of the second epitaxial layer to achieve charge balance in a p/n superjunction of the semiconductor device.

In yet another embodiment, the semiconductor device can further include a lightly doped first conductivity type epitaxial layer disposed between the first epitaxial layer and the substrate.

In yet another embodiment, of the semiconductor device, the first epitaxial layer further includes multiple layers with different doping concentrations.

In yet another embodiment, of the semiconductor device, the trench has an angle that varies according to a current path and a trench fill.

In another embodiment, a second semiconductor device includes a first epitaxial layer of a first conductivity type disposed over a substrate of a first conductivity type and a trench formed in the epitaxial layer. The trench includes a second epitaxial layer grown along the sidewalls and bottom of the trench, a dielectric material disposed in the trench in between the second epitaxial layer and filling a portion of the trench, a gate oxide layer disposed over the dielectric material and over the second epitaxial layer along the sidewalls of the trench which is not covered by the dielectric, and a gate disposed over the gate oxide layer. The second epitaxial layer is doped with a dopant of second conductivity type.

In yet another embodiment, the second semiconductor device can further include a mesa disposed between a plurality of trenches, wherein the mesa is diffused with dopants of the second epitaxial layer to achieve charge balance in a p/n superjunction of the semiconductor device.

In yet another embodiment, the second semiconductor device can further include a lightly doped first conductivity type epitaxial layer disposed between the first epitaxial layer and the substrate.

In yet another embodiment of the second semiconductor device, the first epitaxial layer further includes multiple layers with different doping concentrations.

In yet another embodiment of the second semiconductor device, the trench has an angle that varies according to a current path and a trench fill.

Further areas of applicability of the present disclosure will become apparent from the detailed description provided hereinafter. It should be understood that the detailed description and specific examples, while indicating various embodiments, are intended for purposes of illustration only and are not intended to necessarily limit the scope of the disclosure.

### BRIEF DESCRIPTION OF THE DRAWINGS

A further understanding of the nature and advantages of the invention may be realized by reference to the remaining portions of the specification and the drawings, presented below. The Figures are incorporated into the detailed description portion of the invention.

FIG. 1A illustrates a vertical channel MOSFET device with supetjunction that includes a thin doped epitaxial layer grown on the inside of the trench walls, in accordance with an embodiment of the invention.

FIG. 1B illustrates the vertical channel MOSFET device illustrated in FIG. 1A with a depletion region formed after the source/drain reverse bias is applied to the superjunction.

FIG. 1C illustrates a lateral channel MOSFET device with supetjunction that includes a thin doped epitaxial layer grown on the inside of the trench walls, in accordance with another embodiment of the invention.

FIG. 1D illustrates the lateral channel MOSFET device with supetjunction that includes a thin doped epitaxial layer grown on the inside of the trench walls, in accordance with another embodiment of the invention.

FIGS. 2A-2G are simplified cross section views at various stages of fabricating a MOSFET with supetjunction, in accordance with one embodiment of the invention.

FIG. 3A is an illustration showing a conventional way of doping the sidewall of a trench to form a doped sidewall in the trench.

FIG. 3B is an illustration showing the thin epitaxial layer which is grown on the sidewalls and bottom of a trench using an epitaxial growth techniques instead of the doping techniques illustrated FIG. 3A.

FIG. 4A is an illustration showing a thin epitaxial layer grown on the sidewalls and bottom of a trench using a selective epitaxial growth technique.

FIG. 4B is an illustration showing a thin epitaxial layer grown on the sidewalls and bottom of a trench using a non-selective epitaxial growth technique.

FIG. 5A is an illustration showing the top surfaces of an epitaxial (p-type) layer and a thin doped epitaxial (n-type) layer after having been flattened using a silicon etch process.

FIG. 5B is an illustration showing the top surfaces of an epitaxial (p-type) layer and a thin doped epitaxial (n-type) layer after having been flattened using a chemical mechanical planarization process.

FIG. 6 is a flowchart illustrating a method of forming a vertical channel MOSFET device with superjunction having different pitches and which includes a thin doped epitaxial layer grown on the inside of the trench walls.

### DETAILED DESCRIPTION

In the following description, for the purposes of explanation, specific details are set forth in order to provide a thorough understanding of the invention. However, it will be apparent that the invention may be practiced without these specific details. For example, the conductivity type (n- and p-type) can be reversed accordingly for p-channel devices. The same or similar techniques used to form the supetjunction structure can be applied to devices other than MOSFET devices, such as for example, IGBT, BJT, JFET, SIT (Static Induction Transistor), BSIT (Bipolar Static Induction Transistor), Thyristors, etc.

Embodiments of the present invention provide techniques for fabricating MOSFET devices with supetjunctions having high breakdown voltages with competitively low specific resistance. The techniques for fabricating these MOSFET devices with superjunctions will reduce the fabrication costs as compared with conventional techniques. These techniques include growing a thin epitaxial layer on the sidewalls and bottom of a trench using epitaxial growth techniques. These techniques are better for manufacturing than are sidewall doping techniques and are more suitable for high voltage MOSFET devices than the sidewall doping techniques including angled implants.

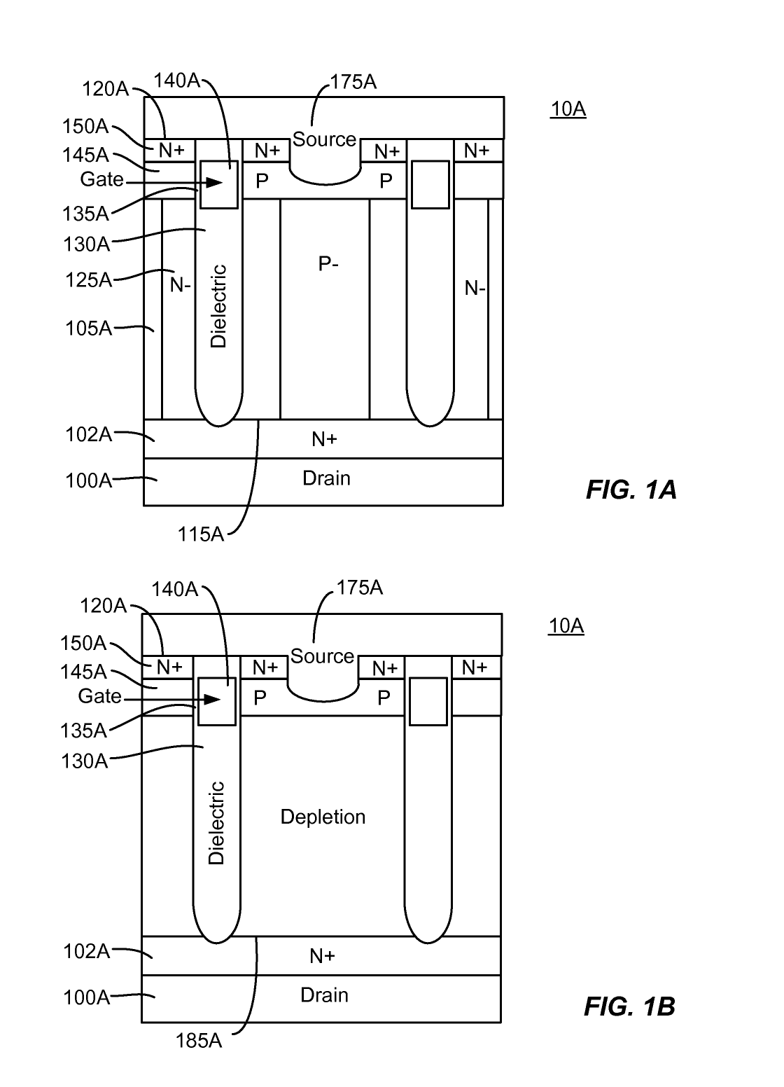

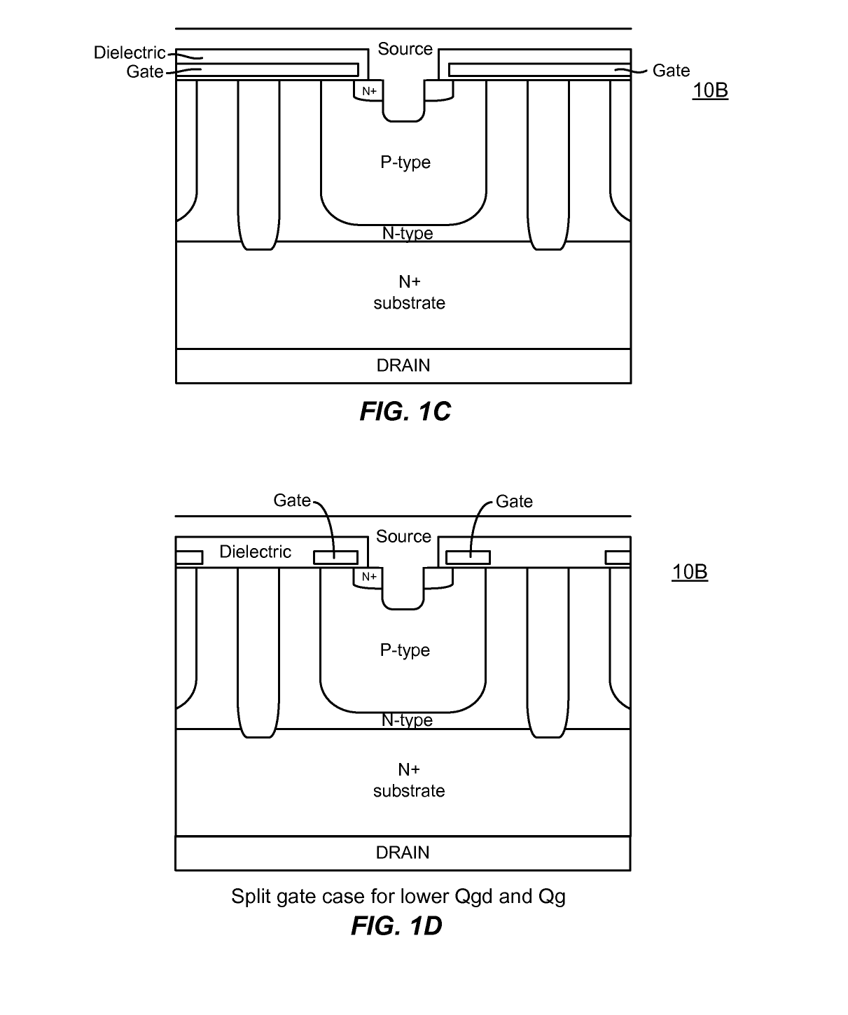

Growing a thin epitaxial layer on the sidewalls and bottom of a trench using epitaxial growth techniques and filling the trench with dielectric material can reduce defects within the epitaxial material in the trench compared to filling completely the trench with epitaxial layer because the new technique can avoid having voids within the trench area more easily. The dielectric material can be deposited so that a highly conformal dielectric material is formed. The dielectric material can later be flowed at relatively low temperatures to remove any voids. In addition, having void defects within the dielectric is not a serious problem because there is a thick dielectric material vertically formed to support high voltage. On the other hand, having void defects within silicon epi can lead to serious failure such as premature break and high leakage current. The new technique can reduce the likelihood of having premature break down and high leakage. In the architectures illustrated in FIGS. 1A-1D, the direction of the electric field is lined up with the trench direction within the thick bottom oxide (TBO) region once the depletion region is formed. Even if some defects are formed in the TBO region, the MOSFET device can still have high oxide thickness (along the vertical length) to sustain the voltage.

FIG. 1A illustrates a vertical channel MOSFET device 10A with superjunction that includes a thin doped epitaxial layer grown on the inside of the trench walls, in accordance with an embodiment of the invention. The MOSFET device 10A includes a drain 100A, a heavily doped N substrate 102A, an epitaxial (p-type) layer 105A, a trench 115A, a mesa 120A, a thin doped epitaxial (n-type) layer 125A, a dielectric 130A, a gate oxide layer 135A, a gate (polysilicon layer) 140A, a p-well region 145A, a source region 150A, and a source electrode region 175A. The source electrode region 175A is located in an upper portion of the device 10A and the substrate with drain 1 OOA is located in the bottom portion of the device. The gate 140A of the trench MOSFET is isolated between the bottom oxide region and an insulating cap located directly above the gate and below the source electrode region 175A. At the same time, the gate 140A is also insulated from then-type thin doped epitaxial layer 125A which, along with the ptype epitaxial layer 1 05A, form the PN junction of a super-junction structure. With such a configuration, the gate 140A of the MOSFET can be used to control the current path in the semiconductor device 10A.

The operation of the semiconductor device 10 is similar to other MOSFET devices. For example, like a MOSFET device, the semiconductor device operates normally in an off-state with the gate voltage equal to 0. When a reverse bias is applied to the source and drain with gate voltage below the threshold voltage, the depletion region 185A can expand and pinch off the drift region, as shown in FIG. 1B. FIG. 1B illustrates the vertical channel MOSFET device illustrated in FIG. 1A with a depletion region formed after the source/drain reverse bias is applied to the superjunction.

The MOSFET device 1OA has an architecture with several features. First, the MOSFET device can achieve high breakdown voltage (2: about 600V) at a low cost. Second, it can have a lower capacitance which, when combined with the higher breakdown voltage, can replace shield-based MOSFET devices operating in the medium voltage range (<about 600V). Third, the MOSFET device can be manufactured at a lower cost than conventional MOSFET devices. The MOSFET device 1 OA can also have less defect related issues relative to other devices. With the devices described herein, the direction of the electric field is close to vertical within the thick bottom oxide (TBO) region once the depletion region 185A is formed. And even if some defect is formed in the TBO region, the devices still have very high oxide thickness (along the vertical length) to sustain the voltage. Thus, the devices described herein can also have a lower leakage current risk.

Further, combining the MOSFET devices in a trench with a super-junction structure can increase the drift doping concentration and can also define a smaller pitch that is able to improve both the current conductivity and the frequency (the switching speed). Further, the supetjunction created by the N trench sidewall and the P epitaxial layer can cause the doping concentration in the drift region to be much higher than other MOSFET structures.

FIG. 1C illustrates a lateral channel MOSFET device 10B with superjunction that includes a thin doped epitaxial layer grown on the inside of the trench walls, in accordance with an embodiment of the invention. The operation of the MOSFET device 10B is also similar to other MOSFET devices. For example, the MOSFET device 10B operates normally in an off-state with the gate voltage equal to 0. When a reverse bias is applied to the source and drain with gate voltage below the threshold voltage, the depletion region can expand and pinch off the drift region, as shown in FIG. 1D. FIG. 1D illustrates the lateral channel MOSFET device illustrated in FIG. 1C with a depletion region formed after the source/drain reverse bias is applied to the superjunction. The lateral channel MOSFET device with superjunction illustrated in FIG. 1D includes a thin doped epitaxial layer grown on the inside of the trench walls, in accordance with another embodiment of the invention. Split gate structures are used in this embodiment to reduce gate charge.

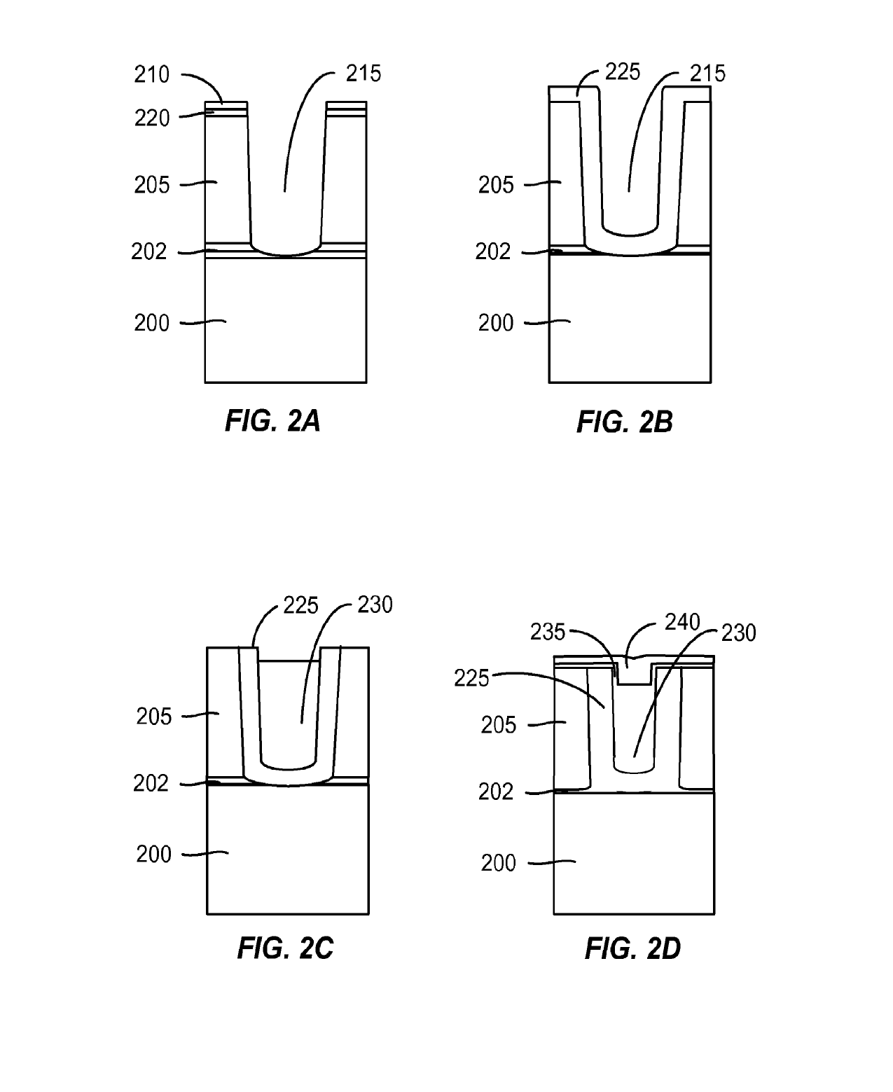

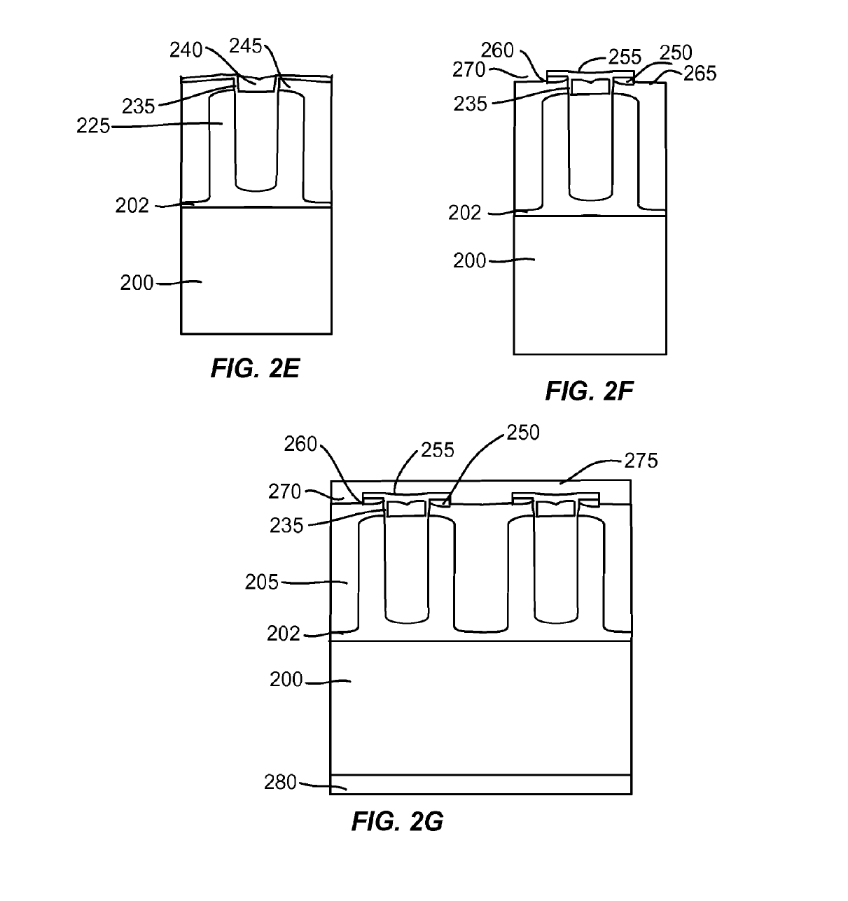

FIGS. 2A-2G are simplified cross section views at various stages of a process for forming a MOSFET with superjunction, in accordance with one embodiment of the invention. In FIGS. 2A-2G, various operations are performed on an epitaxial layer 202, which is disposed on a substrate 200, to form a MOSFET with supetjunction that has a high breakdown voltage (>600V) with competitive specific resistance Rsp. The conductivity types described in these figures can be reversed to make p-channel device. The processes illustrated in FIGS. 2A-2G also provide a lower cost approach than currently exists for fabricating a MOSFET with supetjunction. A typical die will usually have many MOSFET devices with supetjunction, similar to that shown in FIGS. 2A-2G, dispersed throughout the active region of the die in a predetermined frequency. FIG. 2A, which illustrates a cross section of a MOSFET with supetjunction being fabricated, includes a substrate 200, a lightly doped N epitaxial layer 202, an epitaxial (p-type) layer 205, a hard mask layer 210, a trench 215 and a mesa 220. The substrate 200 can be an Ntype wafer which has been previously scribed with a laser to include information such as device type, lot number, and wafer number. The substrate 200 can also be a highly doped N++ substrate. The epitaxial (p-type) layer 205, which is formed over the substrate 200, can be a ptype material made of the same conductivity or different conductivity than the substrate 200. The lightly doped N epitaxial layer 202 can exist between substrate 200 and the epitaxial (p-type) layer 205. In some embodiments, the epitaxial (p-type) layer 205 is made of lightly doped p-type material. The semiconductor region is the lightly doped p-type epitaxial layer 205 formed over a highly doped N-type substrate 200.

The invention is not limited to any specific substrate and most substrates known in the art can be used. Some examples of substrates that can be used in various embodiments include silicon wafers, epitaxial Si layers, bonded wafers such as used in silicon-on-insulator (SOI) technologies, and/or amorphous silicon layers, all of which may be doped or undoped. Also, embodiments can use other semiconducting material used for electronic devices including SiGe, Ge, Si, SiC, GaAs, GaN, InxGayASz, AlxGayASz, AlxGayNz, and/or any pure or compound semiconductors, such as III-V or II-Vls and their variants. In some embodiments, the substrate 200 can be heavily doped with any n-type dopant.

The epitaxial (p-type) layer 205 is epitaxially grown on the lightly doped N epitaxial layer 202 which is on the substrate 200. In some embodiments, the dopant concentration within the epitaxial (p-type) layer 205 is not uniform. In particular, the epitaxial (p-type) layer 205 can have a lower dopant concentration in a lower portion and a higher dopant concentration in an upper portion. In other embodiments, the epitaxial (p-type) layer 205 can have a concentration gradient throughout its depth with a lower concentration near or at the interface with the substrate 200 and a higher concentration near or at the upper surface. The concentration gradient along the length of the epitaxial (p-type) layer 205 can be monotonically decreasing and/or discretely or step-wise decreasing. The concentration gradient can also be obtained by using multiple epitaxial layers (i.e. 2 or more) where each epitaxial layer can contain a different dopant concentration. In one embodiment where multiple layers are used, each successive epitaxial layer is deposited on the previously deposited epitaxial layer (or the lightly doped N epitaxial layer 202 which is on the substrate 200) while being in-situ doped to a higher concentration. In one embodiment, the epitaxial (p-type) layer 205 includes a first epitaxial Si layer with a first concentration, a second epitaxial Si layer with a higher concentration, a third epitaxial Si layer with an even higher concentration, and a fourth epitaxial Si layer with the highest concentration.

The hard mask layer 210, which is also grown over the epitaxial (p-type) layer 205, is used later to define trench 215 etch areas. The thickness of the hard mask 210 depends upon photo resist type and thickness used to define trench critical dimensions (CD) and depth. In one embodiment, the hard mask 210 oxide is thermally grown. In another embodiment the hard mask 210 oxide is deposited (i.e sputter, CVD, PVD, ALD, or combination of deposition and thermal growth). The hard mask layer 210 can also be used for field photolithography and defines future field oxide and alignment targets.

The trenches 215 are formed by depositing and patterning a photoresist layer over the top of the hard mask 215 and forming openings in the hard mask 210 where trench 215 will be etched later. The openings in the hard mask layer 210 can be formed using an etch process. After the openings are formed in the hard mask layer 210, the exposed photo resist is removed using oxygen plasma resist strip. The trenches 215 are formed by etching. The etching process can involve using gaseous etchants such as, for example, SF6/He/02 chemistries. This etching process also forms mesa region 220 which extends between two trenches 215. In some embodiments the mesa has a width that can range from about 0.1 to about 100) lm. The etching process is selected so that the etching is selective to silicon rather than the hard mask layer 210 material.

The epitaxial (p-type) layer 205 can then be etched until the trench 215 has reached a predetermined depth and width in the epitaxial (p-type) layer 205. The trench 215 is formed in the epitaxial (p-type) layer 205 so that the bottom of the trench 215 extends down and reaches anywhere in the epitaxial (p-type) layer 205 or substrate 200. In some embodiments, the trenches are etched to a depth ranging from 0.1) lm to 1 00) lm. In other embodiments the trench 215 is etched to a depth ranging from 1.0) lm to 1.5) lm. The depth, width and aspect ratio of the trench 215 can be controlled so that a later deposited oxide layer fills in the trench without the formation of voids. In some embodiments, the aspect ratio of the trench can range from about 1:1 to about 1:50. In other embodiments, the aspect ratio of the trench can range from about 1:5 to about 1:15.

In some embodiments, the sidewall of the trench 215 is not perpendicular to the top surface of the epitaxial (p-type) layer 205. Instead, the angle of the trench 215 sidewalls can range from about 60 degrees relative to the top surface of the epitaxial (p-type) layer 205 to about 90 degrees (i.e. a vertical sidewall) relative to the top surface of the epitaxial (p-type) layer 205. The trench angle can also be controlled so that a later deposited oxide layer (or other material) fills in the trench 215 without forming voids.

FIG. 2B, which illustrates a cross section of a MOSFET with superjunction being fabricated, includes a substrate 200, a lightly doped N epitaxial layer 202, an epitaxial (p-type) layer 205, a trench 215, a mesa 220, and a thin doped epitaxial (n-type) layer 225. The thin doped epitaxial (n-type) layer 225 is grown on the sidewalls and bottom of the trench 215 as well as on top of the top surface of the epitaxial (p-type) layer 205. The epitaxial layer 225, which can be grown, can be thin and conformal. The thickness and doping concentration can vary through the trench depth to improve the charge balance action in the drift region. For example, the thickness and doping concentration can either increase or decrease with the trench depth gradually or as step-functions.

FIG. 2C, which illustrates a cross section of a MOSFET with superjunction being fabricated, includes a substrate 200, a lightly doped N epitaxial layer 202, an epitaxial (p-type) layer 205, a trench 215, a mesa 220, a thin doped epitaxial (n-type) layer 225, and a dielectric 230. The dielectric 230 is formed in the trench 215 in between the thin doped epitaxial (n-type) layer 225, which was previously grown. The dielectric 230 can be formed using a subatmospheric chemical vapor deposition (SACVD) process, which provides a dielectric layer 230 having excellent coverage and void free. But, any other deposition process can be used as well. The dielectric material can be any insulating or semi-insulating materials, for example, oxides and nitrides. The top of the MOSFET can be also planarized using chemical mechanical planarization (CMP) or an etching process so that the epitaxial (p-type) layer 205 and the thin doped epitaxial (n-type) layer 225 are substantially planar. The dielectric layer 230 can be also etched back so that its top surface is below the top surface of the epitaxial (p-type) layer 205 and the top surface of the thin doped epitaxial (n-type) layer 225. The dielectric layer 230 can be etched back using an oxide etch back process when oxide was used for the dielectric layer.

In some embodiments, the dielectric layer 230 can be formed by depositing an oxide material until it overflows the trenches 215. The thickness of the oxide layer 230 can be adjusted to any thickness needed to fill the trench 215. The deposition of the oxide material can be carried out using any known deposition process, including any chemical vapor deposition (CVD) processes, such as SACVD which can produce a highly conformal step coverage within the trench. If needed, a reflow process can be used to reflow the dielectric material, which will help reduce voids or defects within the oxide layer. After the dielectric layer 230 has been deposited, an etch-back process can be used to remove the excess oxide material. After the etch-back process, the dielectric 230 region is formed in the bottom of the trench 215. A planarization process, such as any chemical and/or mechanical polishing, can be used in addition to (whether before or after), or instead of, the etch-back process. Optionally, a high quality oxide layer can be formed prior to depositing the dielectric layer 230, which can also be a thermally grown oxide. In these embodiments, the high quality oxide layer can be formed by oxidizing the epitaxial (p-type) layer 205 in an oxidizing atmosphere until the desired thickness of the high quality oxide layer has been grown. The high quality oxide layer can be used to improve the oxide integrity and filling factor, thereby making the oxide layer 230 a better insulator.

FIG. 2D, which illustrates a cross section of a MOSFET with supetjunction being fabricated, includes a substrate 200, a lightly doped N epitaxial layer 202, an epitaxial (p-type) layer 205, a trench 215, a mesa 220, a thin doped epitaxial (n-type) layer 225, a dielectric 230, a gate oxide layer 235 and a polysilicon 240. The gate oxide layer 235 is formed on the thin doped epitaxial (n-type) layer 225 which coats the sidewalls of the trench 215 and goes over the top surface of the epitaxial (p-type) layer 205 and the top surface of the thin doped epitaxial (n-type) layer 225. The gate oxide layer 235 can be formed by any process which oxidizes the exposed silicon in the sidewalls of the trench until the desired thickness is grown. The polysilicon 240 is deposited over the thin gate oxide 235 in the trench above a gate oxide layer, which is above the thin doped epitaxial (n-type) layer 225. When the polysilicon 240 is deposited, the polysilicon 240 covers the gate oxide 235 which was formed over the top surface of the epitaxial (p-type) layer 205 and the top surface of the thin doped epitaxial (n-type) layer 225.

The polysilicon 240 can alternatively be any conductive and/or semiconductive material, such as, for example, a metal, silicide, semiconducting material, doped polysilicon, or combinations thereof. The conductive layer can be deposited by deposition methods such as, for example, CVD, PECVD, LPCVD or sputtering processes using the desired metal as the sputtering target. In some embodiments the conductive layer 240 can be deposited so that it fills and overflows over the upper part of the trench 215. In some embodiments, the gate can be formed by removing the upper portion of the conductive layer 240 using etch-back processes. The result of the removal process leaves a conductive layer 240 overlying the gate oxide region 235 in the trench 215 and sandwiched between the gate oxide layers 235. In some embodiments, a gate can be formed so that its upper surface is substantially planar with the upper surface of the epitaxial (p-type) layer 205.

FIG. 2E, which illustrates a cross section of a MOSFET with superjunction being fabricated, includes a substrate 200, a lightly doped N epitaxial layer 202, an epitaxial (p-type) layer 205, a trench 215, a mesa 220, a thin doped epitaxial (n-type) layer 225, a dielectric 230, a gate oxide layer 235, a polysilicon 240, and a p-well region 245. The polysilicon 240 has been etched back so that its top is leveled with or below the surface oxide which was formed during the gate oxide formation. The p-well region 245 is formed in the top region of the epitaxial (ptype) layer 205 and the thin doped epitaxial (n-type) layer 225, starting from its top surface below the gate oxide layer 235 and extending downward into the epitaxial (p-type) layer 205 and the thin doped epitaxial (n-type) layer 225. The p-well region 245 can be formed using implantation and drive processes. For example, in some embodiments, the p-well region 245 can be formed by implanting a p-type dopant in the upper surface of the epitaxial (p-type) layer 205 and then driving-in the dopant.

FIG. 2F, which illustrates a cross section of a MOSFET with superjunction being fabricated, includes a substrate 200, a lightly doped N epitaxial layer 202, an epitaxial (p-type) layer 205, a trench 215, a mesa 220, a thin doped epitaxial (n-type) layer 225, a dielectric 230, a gate oxide layer 235, a polysilicon 240, a p-well region 245, a source region 250, an insulating layer 255, a contact region 260, a heavy body implant region 265 and an opening 270. The source region 250 is formed adjacent to the trench 215 and in the epitaxial (p-type) layer 205 starting from its top surface below the gate oxide layer 235 and extending downward into the epitaxial (p-type) layer 205. The source region 250 can be formed using implantation and drive processes. The overlying insulating layer 255 is used to cover the top surface of the polysilicon 240, which acts as a gate electrode. In some embodiments, the overlying insulating layer 255 includes any dielectric material containing Band/or P, including borophosphosilicate glass (BPSG), phosphosilicate glass (PSG), or borosilicate glass (BSG) materials. In some embodiments, the overlying insulating layer 255 may be deposited using any CVD process until the desired thickness is obtained. Examples of the CVD processes include PECVD, APCVD, SACVD, LPCVD, HDPCVD, or combinations thereof. When BPSG, PSG, or BSG materials are used in the overlying insulating layer 255, they can be reflowed. The contact region 260 can be formed by making an opening 270 to the exposed top surface of the p-well region 245 and the source region 250. The heavy body implant region 265 is formed in the epitaxial (p-type) layer 205 adjacent to the contact region 260. The heavy body implant region 265 can be performed using a p-type dopant. The opening 270 is formed by etching an opening in the contact region 260 and the p-well region 245. Opening 270 can be formed using masking and etching process until the desired depth (into the p-well region 245) is reached. In some embodiments a self alignment technique can be used to form the opening 270.

FIG. 2G, which illustrates a cross section of a MOSFET with supetjunction being fabricated, includes a substrate 200, a lightly doped N epitaxial layer 202, an epitaxial (p-type) layer 205, a trench 215, a mesa 220, a thin doped epitaxial (n-type) layer 225, a dielectric 230, a gate oxide layer 235, a polysilicon 240, a p-well region 245, a source region 250, an insulating layer 255, a contact region 260, a heavy body implant region 265, and a source electrode region 275 formed in the opening 270. The source electrode region 275 can be deposited over the top portions of the insulation layer 255 and the contact region 260. The source electrode region 275 can include any conductive and/or semiconductive material such as, for example, any metal, silicide, polysilicon, or combinations thereof. The source electrode region 275 can be deposited by deposition processes, which include chemical vapor deposition processes (CVD, PECVD, LPCVD) or sputtering processes using the desired metal as the sputtering target. The source electrode region 275 will also fill in the opening 270.

The drain 280 can be formed on the backside of the substrate 200. The drain 280 can be formed before or after the source electrode region 275 has been formed. In some embodiments, the drain 280 can be formed on the backside by thinning the backside of the substrate 200 using processes such as grinding, polishing, or etching. A conductive layer can then be deposited on the backside of the substrate 200 until the desired thickness of the conductive layer of the drain 280 is formed.

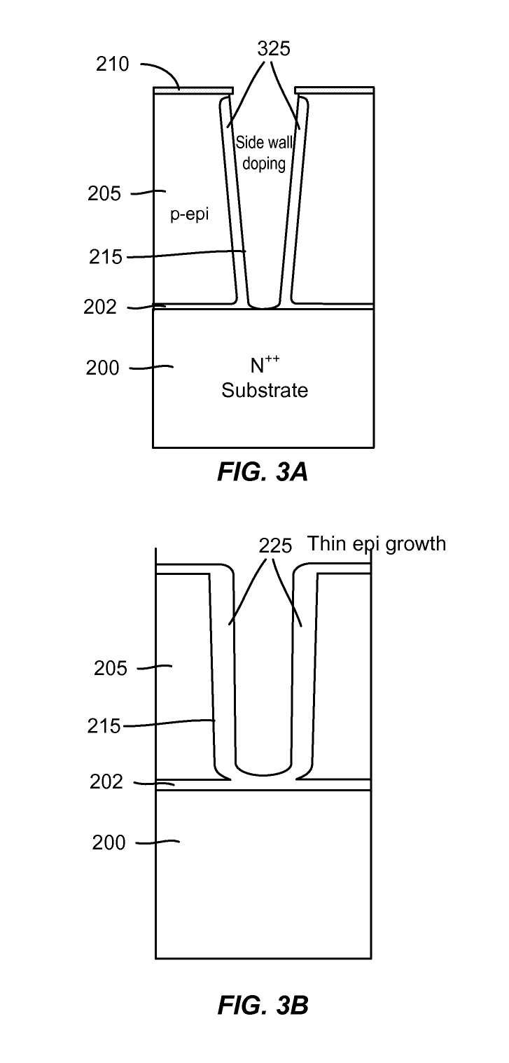

FIG. 3A is an illustration showing a conventional way of doping the sidewall of trench 215 to form a doped sidewall325 on the trench walls. FIG. 3A shows that the sidewalls of the trench 215 are doped with ann-type dopant which implants then-type dopants to the desired width. After the doping process, the dopants can be further diffused using diffusion or drive-in process. This sidewall doping process can be performed using any angled implant process, a gas phase doping process, a diffusion process, depositing doped materials (poly silicon, BPSG, etc). After the doping process the dopants are driven into the side wall. An angled implantation process can be used with an angle ranging from about 0 degrees (a vertical implant process) to about 45 degrees.

FIG. 3B is an illustration showing the thin doped epitaxial (n-type) layer 225 which is grown on the sidewalls and bottom of the trench, as well as on top of the an epitaxial (p-type) layer 205, using an epitaxial growth techniques instead of the doping techniques discussed above with reference to FIG. 3A. The thin doped epitaxial (n-type) layer 225 provides a MOSFET that has better breakdown voltage ratings, which range from 200V to above 700V, than it would have using the doped sidewall315, discussed above with reference to FIG. 3A. The thin doped epitaxial (n-type) layer 225 also provides a MOSFET which has less variation sensitivity to trench angle and depth than it would have using the doped sidewall315, discussed above with reference to FIG. 3A. The side wall-doping method including the angled implantation can be limited by the trench depth because the deeper the trench is, the harder it is to get sufficient doping concentration on the wall. For example, the angled implantation should use lower angle (closer to 0, which is vertical implantation angle), which significantly lowers the effective dose of the implanted dopants. The process repeatability of the side wall doping method is also more sensitive to the trench wall angle because the trench wall angle can significantly affect the effective dose of the implanted dopants.

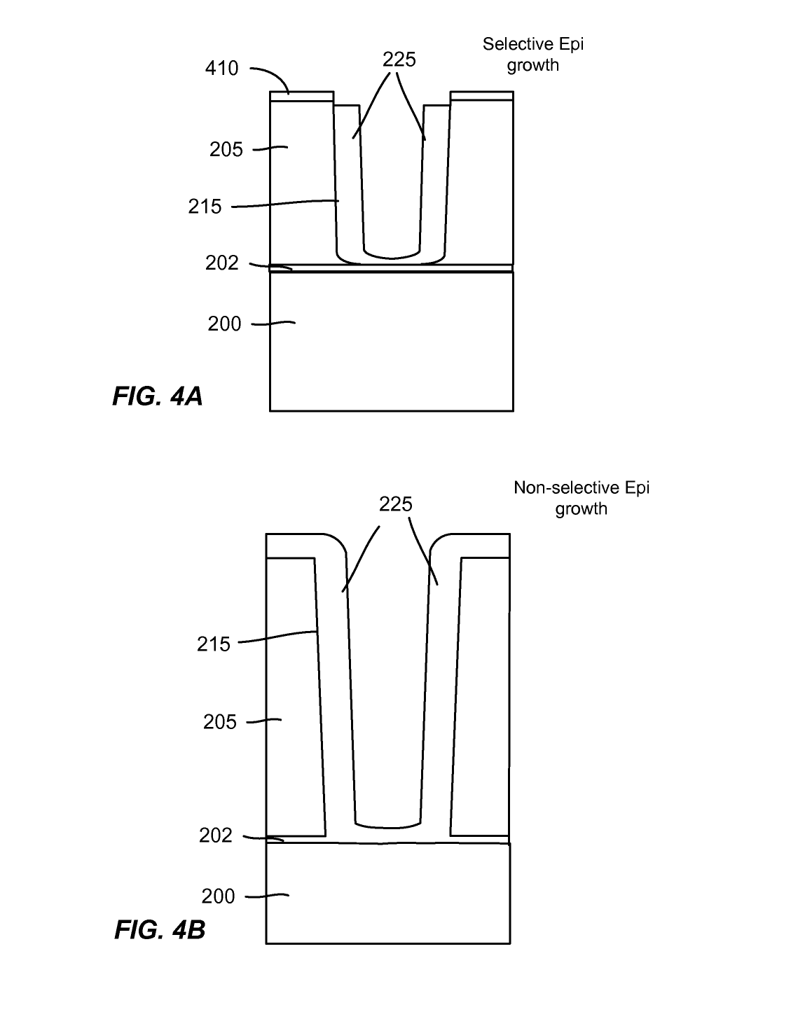

FIGS. 4A and 4B illustrate and compare two techniques used to grow the thin doped epitaxial (n-type) layer 225 in trench 215. FIG. 4A is an illustration showing the thin doped epitaxial (n-type) layer 225 which is grown on the sidewalls and bottom of the trench, using a selective epitaxial growth technique. This selective epitaxial growth process can use an oxide mask 410 which is deposited over the epitaxial (p-type) layer 205. The oxide mask 410 can be deposited over the entire partially fabricated MOSFET and then patterned so that the oxide mask 410 is presented over regions other than the trench 215. With the use of the oxide mask 410, the thin doped epitaxial (n-type) layer 225 is grown inside the trench 215 but not on the epitaxial (ptype) layer 205, which is masked. Some examples of oxide masks that can be used include thermally grown oxide or deposited oxide.

FIG. 4B is an illustration showing the thin doped epitaxial (n-type) layer 225 which is grown on the sidewalls and bottom of the trench, using a non-selective epitaxial growth technique. This non-selective epitaxial growth process grows the thin doped epitaxial (n-type) layer 22S inside the trench 21S as well as on the top surface of the epitaxial (p-type) layer 20S, as was explained above with reference to FIG. 2B.

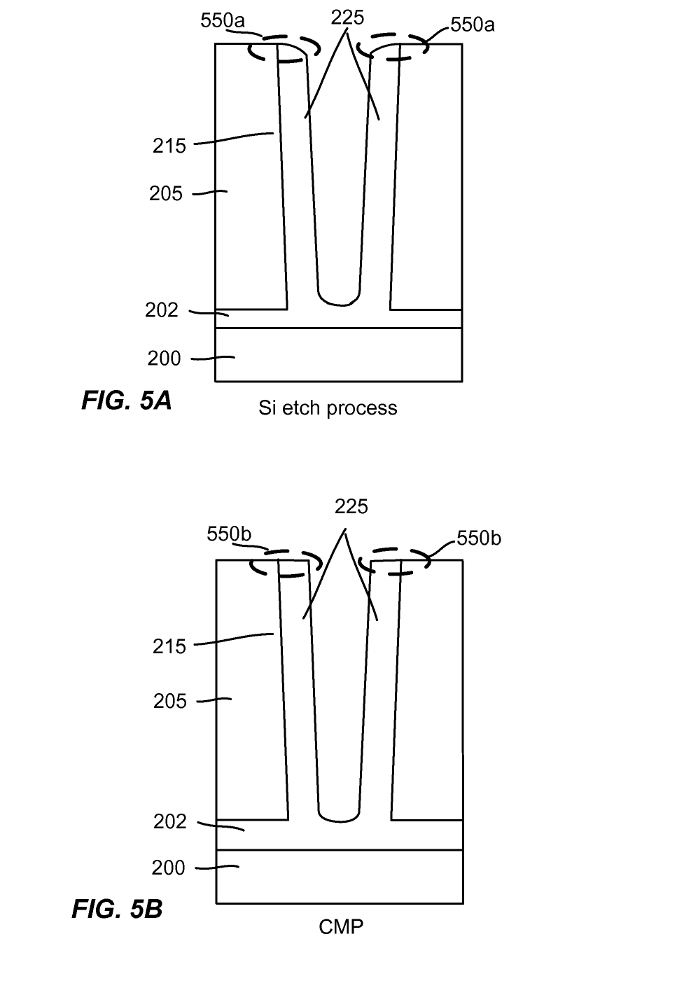

FIGS. 5A and 5B illustrate and compare the results of two techniques used to flatten the top surfaces of the epitaxial (p-type) layer 20S and the thin doped epitaxial (n-type) layer 22S grown inside trench 21S. Although flattening the top surfaces of the epitaxial (p-type) layer 20S and the thin doped epitaxial (n-type) layer 22S is optional, it can produce a MOSFET having a more robust termination structure.

FIG. 5A shows the top surface of the epitaxial (p-type) layer 20S and the top surface of the thin doped epitaxial (n-type) layer 22S after they have been flattened using a silicon etch process. An example of a silicon etch process can include a plasma oxide etch process. Full or partial anisotropic oxide etch can alternatively be used and can be better processes because the trench width is not significantly increased when these processes are used. Using a silicon etch process to flatten the top surfaces of the epitaxial (p-type) layer 20S and the thin doped epitaxial (n-type) layer 22S produces a top surface of the epitaxial (p-type) layer 20S that is substantially flat and a top surface of the thin doped epitaxial (n-type) layer 22S that is rounded. The top surface of the thin doped epitaxial (n-type) layer 22S is flush or co-planar with the top surface of the epitaxial (p-type) layer 20S around where the two top surfaces contact. However, the top surface the thin doped epitaxial (n-type) layer 22S is rounded as it transitions into the sidewalls of the trench. That is, the top surface the thin doped epitaxial (n-type) layer 22S transitions into a sidewall of trench 21S in a rounded manner, instead of forming an abrupt 90 degree transition. This rounded transitions from the top surface of the thin doped epitaxial (n-type) layer 22S into the sidewalls of the trench 21S is shown in the circled region 550a of FIG. 5A.

FIG. 5B shows the top surface of the epitaxial (p-type) layer 20S and the top surface of the thin doped epitaxial (n-type) layer 22S after they have been flattened using a chemical 2S mechanical planarization (CMP) process. Using a CMP process to flatten the top surfaces of the epitaxial (p-type) layer 20S and the thin doped epitaxial (n-type) layer 22S produces substantially flat top surfaces of the epitaxial (p-type) layer 20S and thin doped epitaxial (n-type) layer 22S. The top surface of the thin doped epitaxial (n-type) layer 22S is flush or co-planar with the top surface of the epitaxial (p-type) layer 20S where the two top surfaces contact as well as 30 throughout both surfaces. The CMP process produces a thin doped epitaxial (n-type) layer 22S that has a substantially flat top surface and transitions into a sidewall of trench 21S in an abrupt 90 degree transition. That is, the top surface and sidewalls of thin doped epitaxial (n-type) layer 225 form a substantially right angle (90 degrees), as shown in the circled region 550b of FIG. 5B. Unlike the silicon etch process discussed above with reference to FIG. 5A, the top surface the thin doped epitaxial (n-type) layer 225 is not rounded as it transitions into the sidewalls of the trench 215. The CMP can be done either prior to or after filling the trench with the dielectric materials.

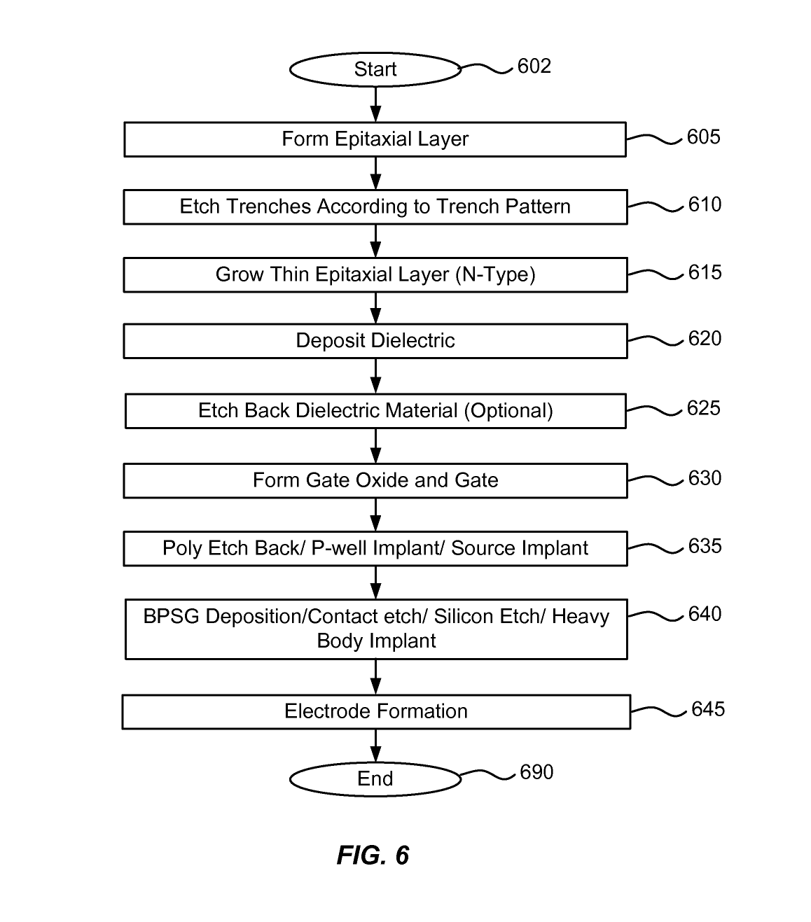

FIG. 6 is a flowchart illustrating a method of forming a vertical channel MOSFET with superjunction (as illustrated in FIG. 1A), in accordance with one embodiment of the invention. The method illustrated in FIG. 6 can be used to fabricate a MOSFET with superjunction where a thin doped epitaxial (n-type) layer 225 which is grown on the sidewalls and bottom of the trench using epitaxial growth techniques instead of doping techniques. The thin doped epitaxial (ntype) layer 225 provides a MOSFET that is more cost effective to fabricate than using conventional methods while having breakdown voltage ratings ranging from 200V to above 700V. The method starts in operation 602 when a substrate 200 having a lightly doped N epitaxial layer 202 is provided. In operation 605 an epitaxial (p-type) layer 205 is formed over the lightly doped N-epitaxiallayer 202. Next in operation 610, a trench 215 is formed in the epitaxial (p-type) layer 205 using etching techniques. In this operation, a hard mask 210 can be grown and patterned over the epitaxial (p-type) layer 205 before the trench 215 is formed in the epitaxial (p-type) layer 205. The hard mask is removed after the trench etch in case that the non-selective epi growth process is followed. Additional details regarding forming trench 215 are discussed earlier with reference to FIG. 2B.

Next, in operation 615, a thin doped epitaxial (n-type) layer 225 is grown on the sidewalls and bottom of the trench 215 as well as on the top surface of the epitaxial (p-type) layer 205. A thin and conformal epi layer can be grown. Alternatively, the thickness and doping concentration can vary through the trench depth to improve the charge balance action in the drift region. For example, the thickness and doping concentration can either increase or decrease with the trench depth gradually or as step-functions. Additional details regarding the growth of thin doped epitaxial (n-type) layer 225 are discussed earlier with reference to FIG. 2B. Next in operation 620, a dielectric 230 is grown and/or deposited in the trench 215 in between the thin doped epitaxial (n-type) layer 225, which was previously grown. The region in trench 230 can be partially filled with dielectric 230 to a predetermined height or can be completely filled with dielectric 230 and then etched back to a predetermined height as shown in optional operation 625. Additional details regarding the growth of dielectric layer 230 are discussed earlier with reference to FIG. 2C. Next in operation 630, the gate oxide layer 235 and polysilicon gate 240 are formed in the trench. The gate oxide layer 235 is grown over the top of the dielectric layer 230 and on the thin doped epitaxial (n-type) layer 225 which coats the sidewalls of the trench 215. The gate oxide layer 235 also partially covers the top surface of the epitaxial (p-type) layer 205 and the top surface of the thin doped epitaxial (n-type) layer 225. The polysilicon 240 is deposited over the thin gate oxide 235 in the trench, which is above the thin doped epitaxial (ntype) layer 225. When the polysilicon 240 is deposited, the polysilicon 240 covers the gate oxide 235 which was deposited over the top surface of the epitaxial (p-type) layer 205 and the top surface of the thin doped epitaxial (n-type) layer 225. Additional details regarding forming the gate oxide layer 235 and polysilicon gate 240 are discussed earlier with reference to FIG. 2D.

In operation 635 the polysilicon 240 etched back, p-well region 245 is implanted and source region 250 is implanted. The polysilicon 240 is etched back so that its top surface is substantially closer to both the top surface of the epitaxial (p-type) layer 205 and the top surface of the thin doped epitaxial (n-type) layer 225. The p-well region 245 is formed in the epitaxial (p-type) layer 205 starting from its top surface below the gate oxide layer 235 and extending downward into the epitaxial (p-type) layer 205. The source region 250 is formed adjacent to the trench 215 and in the epitaxial (p-type) layer 205 starting from its top surface below the gate oxide layer 235 and extending downward into the epitaxial (p-type) layer 205. Both the p-well region 245 and the source region 250 are formed using implantation and drive processes. Additional details regarding the polysilicon 240 etched back, p-well region 245 implant and source region 250 is implant are discussed earlier with reference to FIG. 2E.

Next in operation 640, an insulating layer 255 is deposited over the polysilicon layer 240, the contact regions 260 and silicon regions are etched, and the heavy body implants 265 are formed. The overlying insulating layer, which can be BPSG, is used to cover the top surface of the polysilicon 240, which acts as a gate. The BPSG materials, which are used in the overlying insulating layer 255, can be reflowed. The contact region 260 can be formed on the exposed top surface of the epitaxial (p-type) layer 205. The contact region 260 can be formed by implanting ann-type dopant in the upper surface of the epitaxial (p-type) layer 205 and then driving in the dopant. The heavy body implant region 265 is formed in the epitaxial (p-type) layer 205 below the contact region 260. The heavy body implant region 265 can be performed using a p-type dopant to form a PNP region. An opening 270 can also be formed by etching an opening in the contact region 260 and the p-well region 245. Masking and etching processes can be used to form opening 270 to a predetermined depth (into the p-well region 245). In some embodiments a self alignment technique can be used to form the opening 270. Additional details regarding depositing the insulating layer 255, etching the contact regions and silicon regions, and forming the heavy body implants 265 are discussed earlier with reference to FIG. 2F.

In operation 645, the electrodes are formed. The source electrode region 275 can be deposited in the opening 270 and over the top portions of the insulation layer 255 and the contact region 260. The source electrode region 275 can include any conductive and/or semiconductive material such as, for example, any metal, silicide, polysilicon, or combinations thereof. The drain 280 can be formed on the backside of the substrate 200. The drain 280 can be formed before or after the source electrode region 275 has been formed. In some embodiments, the drain 280 can be formed on the backside by thinning the backside of the substrate 200 using processes such as grinding, polishing, or etching. A conductive layer can then be deposited on the backside of the substrate 200 until the desired thickness of the conductive layer of the drain 280 is formed. Additional details regarding forming the electrodes are discussed earlier with reference to FIG. 2G. Finally, in operation 690, the MOSFET with supetjunction is completed.

Although specific embodiments of the invention have been described, various modifications, alterations, alternative constructions, and equivalents are also encompassed within the scope of the invention. The described invention is not restricted to operation within certain specific embodiments, but is free to operate within other embodiments configurations as it should be apparent to those skilled in the art that the scope of the present invention is not limited to the described series of transactions and steps.

It is understood that all material types provided herein are for illustrative purposes only. Accordingly, one or more of the various dielectric layers in the embodiments described herein may comprise low-k or high-k dielectric materials. As well, while specific dopants are names for then-type and p-type dopants, any other known n-type and p-type dopants (or combination of such dopants) can be used in the semiconductor devices. As well, although the devices of the invention are described with reference to a particular type of conductivity (P or N), the devices can be configured with a combination of the same type of dopant or can be configured with the opposite type of conductivity (Nor P, respectively) by appropriate modifications.

The specification and drawings are, accordingly, to be regarded in an illustrative rather than a restrictive sense. It will, however, be evident that additions, subtractions, deletions, and other modifications and changes may be made thereunto without departing from the broader spirit and scope of the invention as set forth in the claim.

What is claimed is:

1. A semiconductor device comprising:
a semiconductor substrate of a first conductivity type;
a first epitaxial layer of a second conductivity type disposed on the semiconductor substrate;
a trench formed in the first epitaxial layer, the trench terminating within the first epitaxial layer;
a second epitaxial layer of the first conductivity type disposed on a sidewall of the trench and a bottom surface of the trench;
a dielectric material disposed within at least a portion of the trench and within at least a portion of the second epitaxial layer, the second epitaxial layer being disposed between the dielectric material and the substrate;
a gate oxide layer disposed on the sidewall of the trench; and
a gate electrode disposed on the gate oxide layer and within the trench.

2. The semiconductor device of claim 1, wherein the gate oxide is disposed on the second epitaxial layer and on at least a portion of the sidewall of the trench that is not covered by the dielectric.

3. The semiconductor device of claim 1, wherein the gate oxide has a top surface substantially coplanar with a top surface of the first epitaxial layer.

4. The semiconductor device of claim 1, further comprising a third epitaxial layer of the first conductivity type, the third epitaxial layer being disposed between the semiconductor substrate and the first epitaxial layer.

5. The semiconductor device of claim 1, wherein the first epitaxial layer has a doping concentration gradient that varies with a depth of the first epitaxial layer.

6. The semiconductor device of claim 1, wherein the first epitaxial layer includes a first sub-layer disposed on the semiconductor substrate and a second sub-layer disposed on the first sub-layer, the first sub-layer having a lower doping concentration than a doping concentration of the second sub-layer.

7. The semiconductor device of claim 1, wherein a doping concentration of the first epitaxial layer monotonically decreases thorough a depth of the first epitaxial layer from a top surface of the first epitaxial layer to an interface of the first epitaxial layer with the semiconductor substrate.

8. The semiconductor device of claim 1, wherein a thickness of the second epitaxial layer varies through a depth of the trench.

9. The semiconductor device of claim 1, wherein a doping concentration of the second epitaxial layer varies through a depth of the trench.

10. A semiconductor device comprising:
a semiconductor substrate of a first conductivity type;
a first epitaxial layer of the first conductivity type disposed on the semiconductor substrate;
a second epitaxial layer of a second conductivity type disposed on the first epitaxial layer;
a trench formed in the second epitaxial layer, the trench terminating with the first epitaxial layer;
a third epitaxial layer of the first conductivity type disposed on a sidewall of the trench and a bottom surface of the trench;
a dielectric material disposed within at least a portion of the trench and within at least a portion of the third epitaxial layer, the third epitaxial layer being disposed between the dielectric material and the semiconductor substrate;
a gate oxide layer disposed on the sidewall of the trench; and
a gate electrode disposed on the gate oxide layer and on the dielectric material, the gate electrode being disposed within the trench.

11. The semiconductor device of claim 10, wherein a portion of the third epitaxial layer on the bottom surface of the trench terminates within the first epitaxial layer.

12. The semiconductor device of claim 10, wherein the second epitaxial layer includes a plurality of sub-epitaxial layers including a first sub-epitaxial layer disposed on the first epitaxial layer and at least a second sub-epitaxial layer disposed on the first sub-epitaxial layer, the second sub-epitaxial layer having a higher doping concentration than a doping concentration of the first sub-epitaxial layer.

13. The semiconductor device of claim 12, wherein the plurality of sub-epitaxial layers further includes a third sub-epitaxial layer disposed on the second sub-epitaxial layer, the third sub-epitaxial layer having a higher doping concentration than the doping concentration of the second sub-epitaxial layer.

14. The semiconductor device of claim 10, wherein the third epitaxial layer has a thickness that increases with a depth of the trench.

15. The semiconductor device of claim 10, wherein the third epitaxial layer has a doping concentration that increases with a depth of the trench.

16. The semiconductor device of claim 10, wherein the third epitaxial layer has a thickness that decreases with a depth of the trench.

17. The semiconductor device of claim 10, wherein the third epitaxial layer has a doping concentration that decreases with a depth of the trench.
